(19) United States
(12) Patent Application Publication
(10) Pub. No.: US 2024/0044968 A1
(43) Pub. Date: Feb. 8, 2024

(54) METHOD AND APPARATUS FOR DETERMINING OUTPUT CHARGE OF WIDE BANDGAP DEVICES WITHOUT HARDWARE MODIFICATION

(71) Applicant: Tektronix, Inc., Beaverton, OR (US)

(72) Inventors: Vivek Shivaram, Bengaluru (IN); Niranjan R. Hegde, Siddapur (IN); Krishna N H Sri, Bengaluru (IN); Abhishek Naik, Chandavar (IN); Shubha B, Bengaluru (IN); Yogesh M. Pai, Bengaluru (IN); Venkatraj Melinamane, Bengaluru (IN)

(73) Assignee: Tektronix, Inc., Beaverton, OR (US)

(21) Appl. No.: 18/361,672

(22) Filed: Jul. 28, 2023

(30) Foreign Application Priority Data
Aug. 3, 2022 (IN) 202221044476

(51) Int. Cl. G01R 31/26; G01R 31/28; G01R 1/067

(52) U.S. Cl. CPC G01R 31/2603; G01R 31/2889; G01R 1/06788

(57) ABSTRACT

A test and measurement instrument includes a user interface, one or more probes to connect to a device under test (DUT), and one or more processors to take measurements during application of a double pulse test to the DUT to create measurement data, identify a measurement start point, find a measurement stop point, use the measurement data between the measurement start point and the measurement stop point to determine an output charge, Qoss, of the DUT, and display the output charge to a user. A method of determining output charge of a device under test (DUT) includes taking measurements during application of a double pulse test to create measurement data, identifying a measurement start point, finding a measurement stop point, using the measurement data between the measurement start point and the measurement stop point to determine an output charge, Qoss, of the DUT, and displaying the output charge.

### CROSS-REFERENCE TO RELATED APPLICATIONS

This disclosure claims priority under 35 U.S.C. § 119 to Indian Provisional Patent Application No. 202221044476, filed Aug. 3, 2022, titled “METHOD FOR DETERMINING OUTPUT CHARGE (QOSS) OF WBG DEVICES WITHOUT HARDWARE MODIFICATION,” the disclosure of which is incorporated herein by reference in its entirety.

### TECHNICAL FIELD

The present disclosure relates generally to test and measurement instruments and methods, and more particularly to testing wide band-gap semiconductors.

### BACKGROUND

Semiconductor materials used in power electronics are transitioning from silicon to Wide Band Gap (WBG) semiconductors such as silicon carbide (SiC) and gallium nitride (GaN). WBG semiconductors have superior performance at higher power levels in automotive and industrial applications. Test procedures for MOSFETs (metal oxide semiconductor field effect transistors) of MOSFETs or IGBTs (insulated-gate bipolar transistors) commonly involve using the Double Pulse Test (DPT) method. A DPT test generally turns a power switch device under test (DUT) on and off at different current levels to control and measure the device over a full range of operating conditions.

To measure WBG power loss, one needs to characterize device on-resistance, capacitance, and gate charge parameters. The characteristics section of a semiconductor data sheet typically lists the dynamic characteristics of the devices. The output charge known as Qoss is an important parameter for devices which have body diodes.

The accurate measurement of output charge has paramount importance as it directly affects switching speed of a WBG device and the capacitive property of a SiC MOSFET body diode during turn-on. The reverse recovery charge (Qrr) is a property of the power device and consists of the stored bipolar charge that is swept out during the turn-off process, and a capacitive contribution that limits from charging the output capacitance Coss to the DC-link voltage.

At present, engineers find it hard to discern between output charge (Qoss) and reverse recovery charge (Qrr) for WBG devices. Since the WBG solutions are utilized for varying temperature condition, a growing need exists to measure Qoss at different junction temperatures. The reverse current pulses are superimposed with bipolar charge oscillation which leads to large settling time at recovery regions. FIG. 2 shows a graphical representation of the regions of the pulses that may lead to these errors.

Conventional solutions involve circuit-invasive method by placing a gate resistor (R_{g}) at high side device to reduce the capacitive overshoot. To determine a simple characteristic parameter, a DUT may have additional, unnecessary circuit elements which leads to hardware errors like improper soldering of joints.

Other recommendations include determining Qoss on the second pulse of the reverse recovery current. However, Qoss should be separated from Qrr based on the slopes, as shown in FIG. 2. This method will provide incorrect Qoss for WBG devices.

### BRIEF DESCRIPTION OF THE DRAWINGS

FIG. 1 shows reverse current curves with varying pulse regions.

FIG. 2 shows a graphical representation of regions used in current Qoss calculations.

FIG. 3 shows a circuit diagram of parasitic elements in DPT power circuits.

FIG. 4 shows an embodiment of Qoss computed on a first drain current reverse pulse.

FIG. 5 shows Qoss determined on a drain current reverse pulse using an alternative test setup.

FIG. 6 shows Qoss determined on a first drain current reverse pulse where V_{ds-th} is at a threshold level of V_{dspeak}.

FIG. 7 shows a plot of Qoss using I_{d} for varying junction temperature and peak reverse current I_{RR} for V_{ds} at 600V.

FIG. 8 shows a Qoss plot using I_{d} for varying junction temperature and peak reverse current I_{RR} for V_{ds} at 800V

FIG. 9 shows a Qoss plot using V_{ds} and I_{d} for varying junction temperature and peak reverse current I_{RR} for V_{ds} or 600V.

FIG. 10 shows a Qoss plot using V_{ds} and I_{d} for varying junction temperature and peak reverse current I_{RR} for V_{ds} at 800V.

FIG. 11 shows an embodiment of a user interface for Qoss configuration page in a WBG DPT solution in oscilloscope.

FIG. 12 shows an embodiment of a test and measurement instrument.

### DETAILED DESCRIPTION

Embodiments herein apply a double pulse test to a wide-band gap semiconductor device, capture the resulting waveform and perform analysis on the waveform to determine the output charge of the device. The embodiments herein, unlike current approaches, perform this analysis non-invasively, and much more accurately.

In double pulse testing, a test and measurement instrument applies a turn-on pulse to the device, which may be adjusted as needed to reach a desired drain current. This instrument then turns off the first pulse for a short period of time so as to not affect the load current. The instrument then applies a second pulse to the device, typically only long enough for a measurement to be taken, and then turns off the second pulse.

A test and measurement device connected to the device under test (DUT) captures the measurements of the device characteristics during the test. The device may undergo this test multiple times at different temperatures to allow for the most accurate measurement.

The embodiments generally involve using the measurement data to identify a first point in the measurement data, i.e. a measurement start point, and a second point in the measurement data, i.e. a measurement stop point. Determination of the second point varies between the embodiments, but the first point results from finding a first trough in the measurement data. In one embodiment the measurement data is the drain current, I_{d}. In another embodiment the measurement data comprise both the drain current and the low-side drain-source voltage, V_{ds}.

The embodiments here use a measurement found at first pulse of double pulse testing. At the rise of gate voltage, the current I_{d} drops and forms a trough. In some embodiments of test setups, the size of the first trough in the current depends on the junction temperature. Any oscillations due to stored bipolar charge depends on the resistance, blocking capacitor and parasitics.

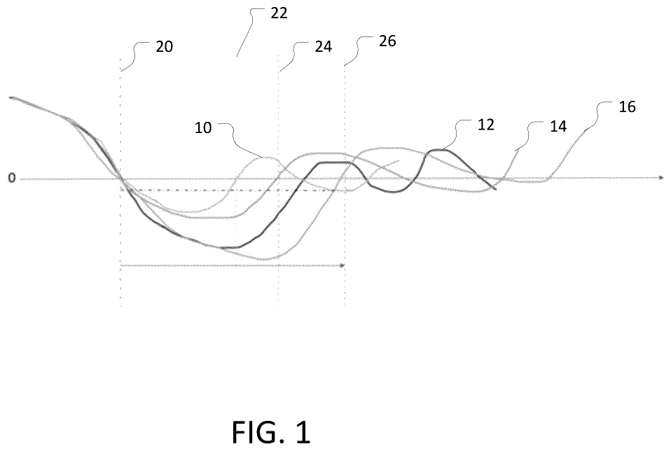

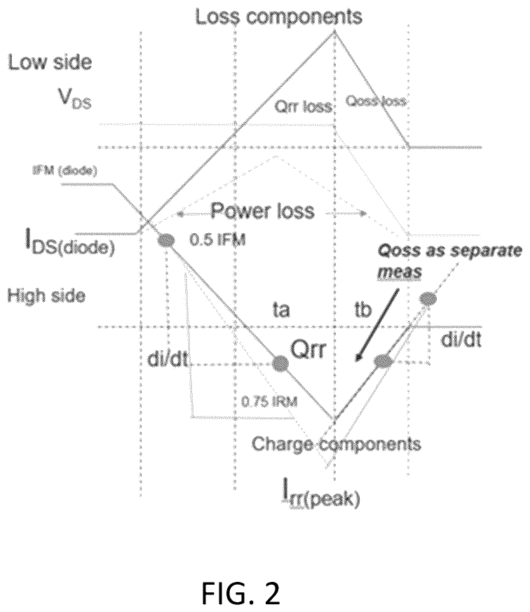

FIG. 1 shows examples of reverse current curves with varying pulse regions. The reverse current curves result from drain current measurements taking from DUTs during double pulse testing. Each of the curves 10, 12, 14 and 16 represent separate tests performed on a DUT. The curves all have a zero crossing point 20, which defines the beginning of the pulse region of interest in time. Line 22 shows the second zero crossing for curve 10, line 24 represents the second zero crossing for curve 14, and line 26 represents the second zero crossing for curve 16.

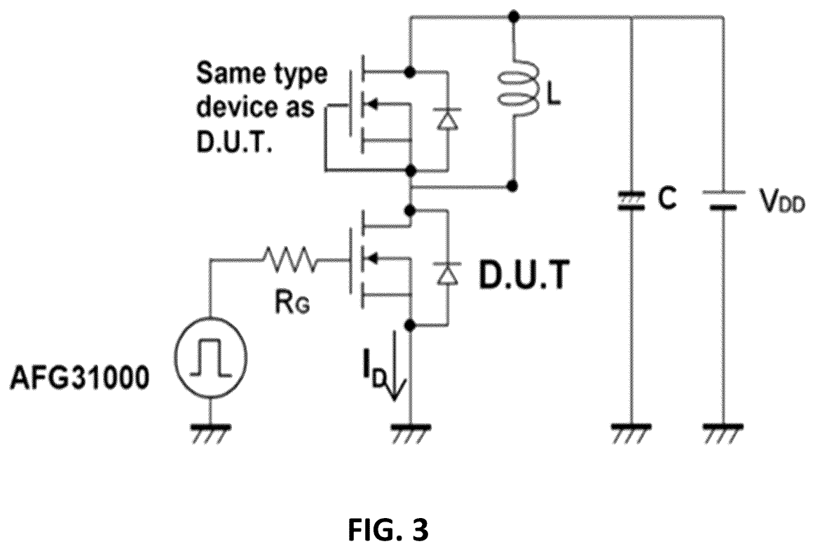

FIG. 3 shows a typical test setup for performing a double pulse test (DPT) on a DUT. There are two switching devices, a “high side” device and a “low side” device, in a half-bridge configuration. One switching device, typically the low side device, is the device under test (DUT) and the second device is typically the same type of device as the DUT. Note the inductive load on the “high” side device. The inductor is used to replicate circuit conditions that may be present in normal device operation. A power supply or SMU can supply the voltage V_{DD}, and an arbitrary function generator (AFG) or other signal generator can output pulses that trigger the gate of the DUT to turn it on to start conduction of the current. An oscilloscope together with appropriate current and voltage probes can be used to measure resulting waveforms from the DUT.

The process for applying the double pulse test and capturing the measurement data may comprise the following. First, one must discharge all the residual charge in active elements of circuit. One embodiment measures the gate voltage, V_{gs}, using a high common mode rejection ratio (CMRR) probe such as TIVP. One embodiment measures the drain source voltage, V_{ds} using a calibrated differential probe and drain current I_{d} using a current viewing resistor.

In one embodiment the double pulse test turns on the DUT using a gate voltage with a correct source connection so that no ringing occurs because of the voltage propagation path. The test will control the pulse width of the gate drive to create the double pulse and the measurements are captured.

After capture, the oscilloscope software may automatically detect the first pulse region of double pulse test using the gate waveform. A first embodiment of a method to determine the Qoss algorithm uses the drain current. The method uses the current measurement as source and finds the first trough using an edge detection algorithm. In this embodiment, the method determines the absolute area under the curve of the data using Equation 1.

$${Q}_{oss} = {\int }_{t 1}^{t 2} \vert {I}_{d} \vert dt \qquad ( 1 )$$

In Equation 1, t1 represents the time of a first zero crossing time, the time of the falling zero crossing, of the current and t2 represents the time of the second zero crossing time of the current, the rising zero crossing time . The Qoss value determined in this embodiment will have minimum variance for multiple current magnitude and junction temperature. The test and instrument method, discussed in more detail below, has a user interface to allow selection to enable or disable the computation with absolute operation on each current sample.

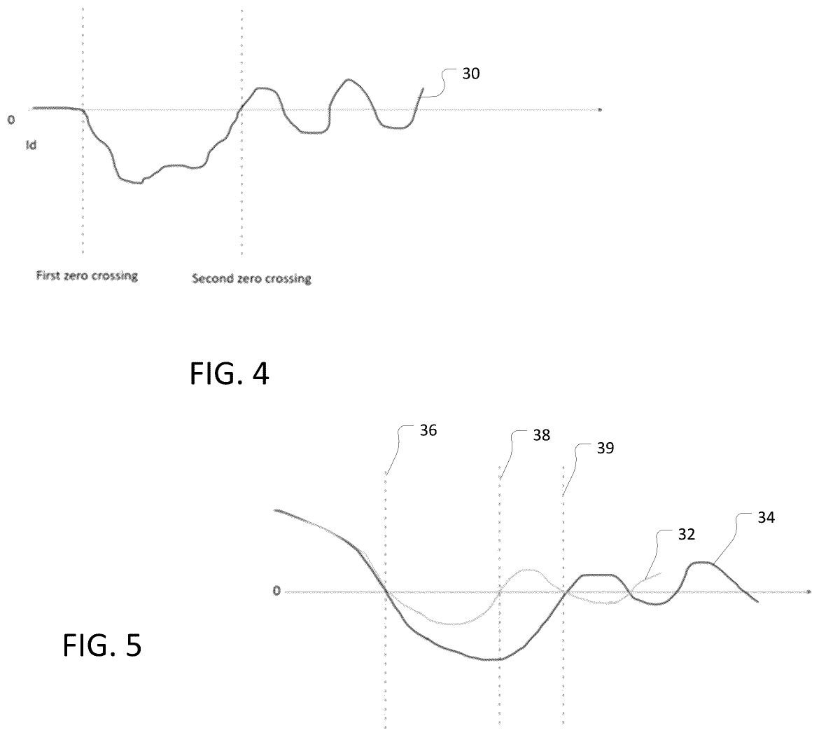

FIG. 4 shows a curve 30 that represents the drain current measurement data taken from a DUT. The falling zero crossing defines the beginning of the pulse region. The methods herein identify this point using an edge detection process that identifies the beginning of the trough in the drain current. In the embodiment above, the second point is the second zero crossing, and the output charge results from integrating the drain current over time between these two points. FIG. 5 shows drain currents for two different curves 32 and 34. Both of these curves have zero crossings at 36, with curve 32 having the second zero crossing at 38 and curve 34 having the second zero crossing at 39.

In a second embodiment, the test and measurement instrument will detect the first pulse region that begins with the first zero crossing, the falling zero crossing. This embodiment uses both the low-side V_{ds} and I_{d}. The method sets the first point to the time at which the first zero crossing time of the current occurs. The method sets the second point as the time at which V_{ds} has reached threshold magnitude V_{ds-th}. These become the first and second points in time over which the curve of the data is integrated, as shown in Equation 2.

$${Q}_{oss} = {\int }_{tId}^{tVds} \vert {I}_{d} \vert dt \qquad ( 2 )$$

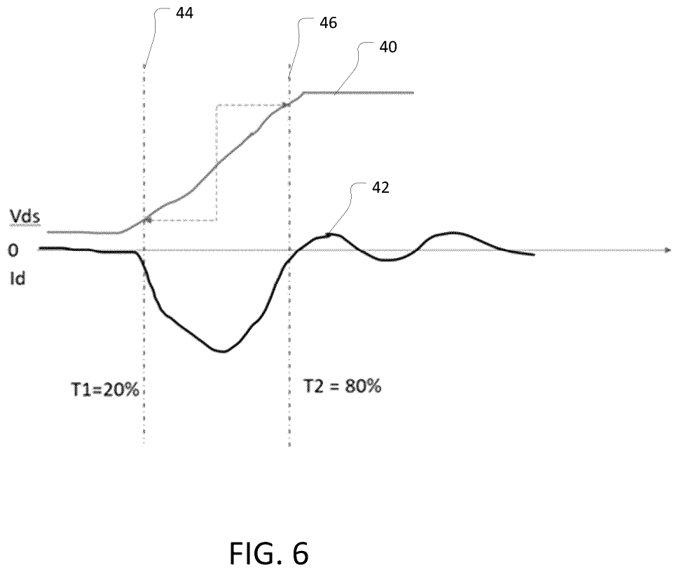

As mentioned above, tId is the time of the first zero crossing of current and tVds is the time at which low-side V_{ds} reached a threshold V_{ds-th}. The threshold of V_{ds} that determines the Qoss may be the first occurrence of settling of the V_{ds} from the left in the first pulse region. Alternatively, it can be a certain percentage of the peak of V_{ds} in the first pulse region. FIG. 6 shows the I_{d} curve 42 and the V_{ds} curve 40, the zero crossing 44 of the drain current, and the point 46, where the drain-source voltage is at 80% of its peak. The user can configure these two points to designate the first and second points, thereby designating the region of interest. The test and measurement instrument allows configuration of V_{ds-th} to accommodate testing of fast and slow switching and also WBG reference designs. The methods of the embodiments allow for configuration to the V_{ds-th} level detection from left or right of the first pulse region, and it may allow for setting of the percentage of the peak value used as the threshold, if the peak percentage is used. The user may configure which occurrence of settling of V_{ds} is used, such as the first one, the last once, etc. The user would make inputs through the user interface. Alternatively, the system may have a default setting, such as using the first occurrence.

The embodiments above rely upon two points in time. The first point in time, the measurement starting point, and the second point in time, the measurement stopping point, define the pulse region used to determine Qoss. The embodiments use a zero crossing time as the first point in time. Typically, this will comprise the falling zero crossing, but could be reversed. In one embodiment, the second point comprises the rising zero crossing. In another embodiment, the second point comprises either the time of settling of V_{ds} or a time at which a threshold percentage of the peak value is reached. Other variations of these point definitions fall within the scope of the claims. The measurement starting time and the measurement stopping time may occur in time order, or may be reversed.

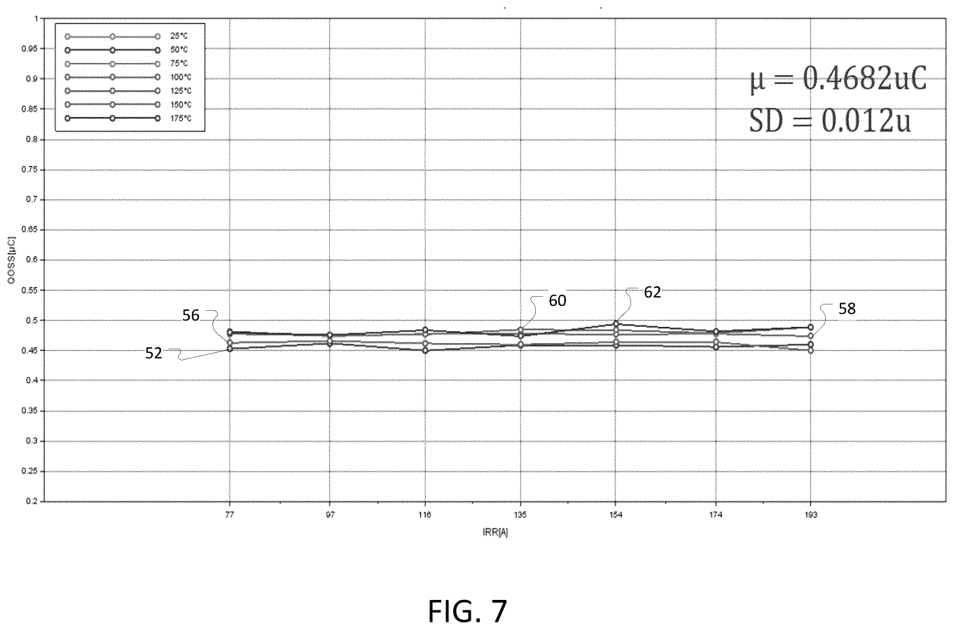

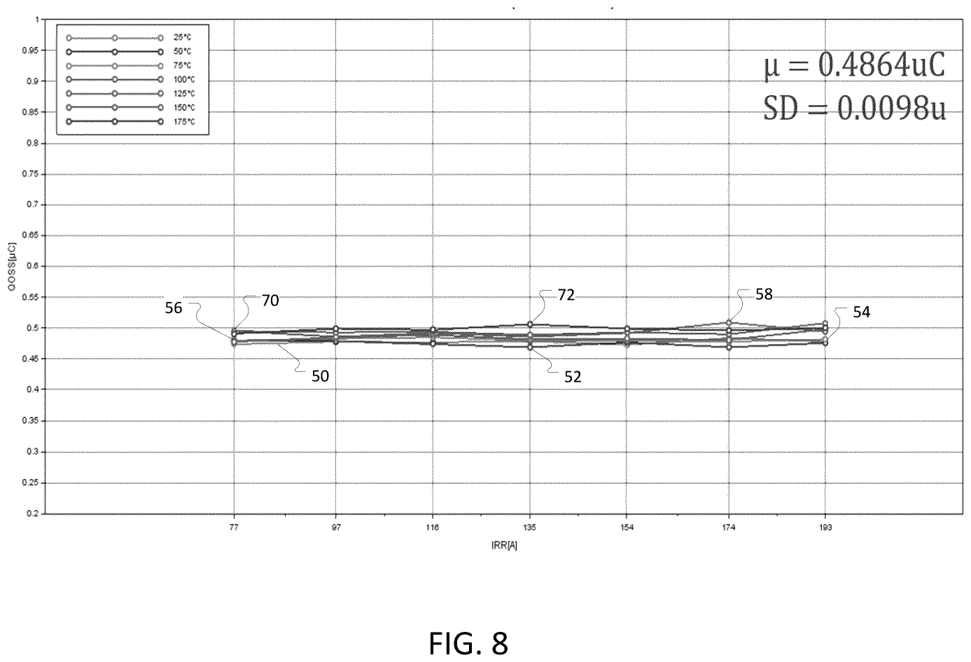

The embodiment of the method to find Qoss that only uses current Id provides Qoss values which are within small standard deviation for varying current and junction temperature as illustrated in FIG. 7 and FIG. 8 for different settling V_{ds}. As seen in FIGS. 7 and 8, Qoss is expected to increase for higher settling V_{ds} because of high initial charge intake and confirmed with device physics. In FIGS. 7-10, each temperature has the same reference number. Reference number 50 designates 25° C. (not shown in FIG. 7), 52 designates 50° C., 54 designates 75° C., 56 designates 100° C., 58 designates 125° C., 60 designates 150° C., and 62 designates 175° C.

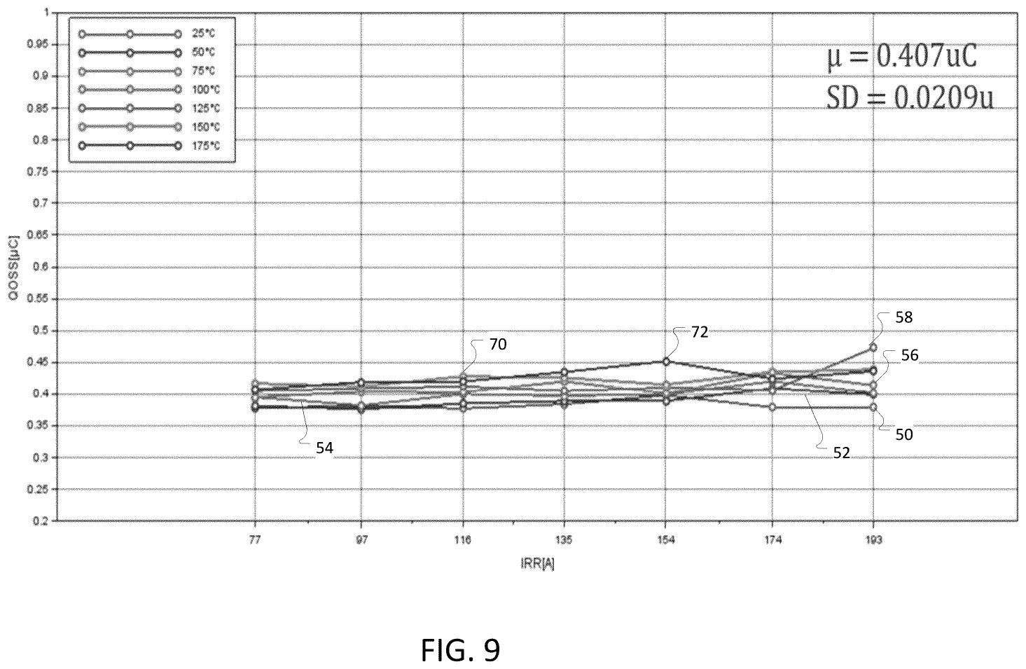

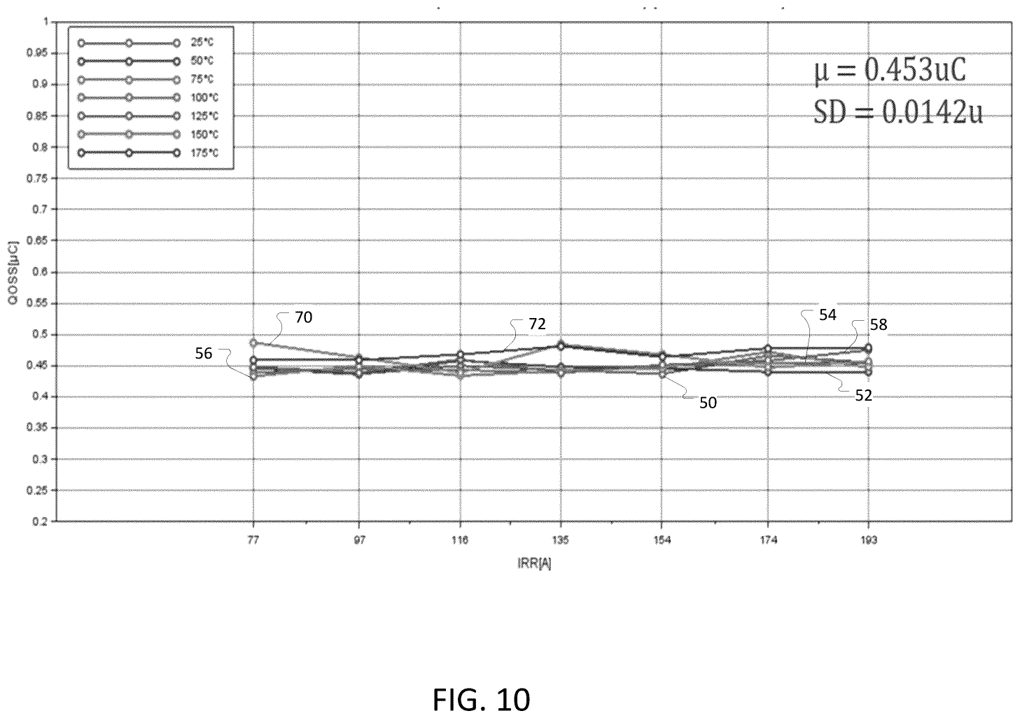

The alternative embodiment uses V_{ds} and I_{d} to compute Qoss. The V_{ds-th} level parameter may be set at the first occurrence of settling of V_{ds}. The first occurrence of the V_{ds-th} level in first pulse region may also provide the stopping point for integration as seen in Equation 2. As shown in FIGS. 9 and 10, the computed Qoss magnitudes have low variance around the mean.

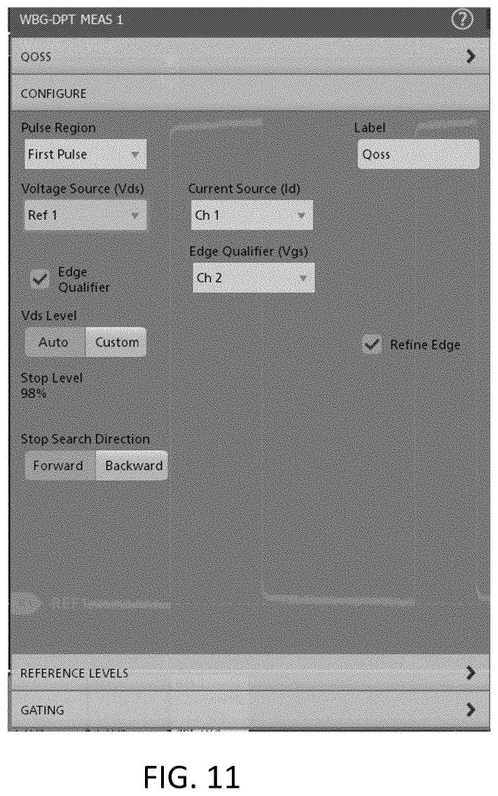

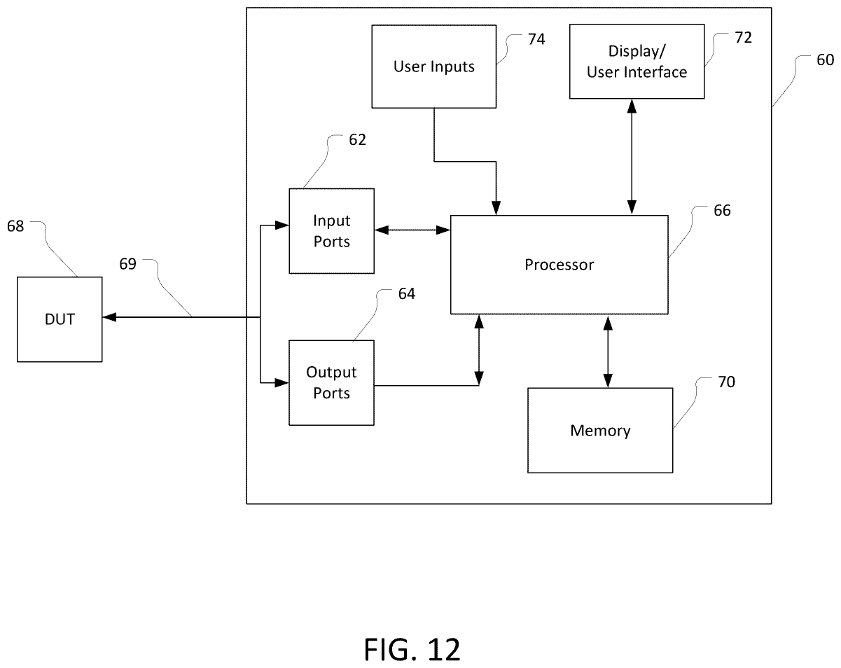

Embodiments of the test and measurement allow the user to configure which source they want to use for the second point, either the drain current, or the drain-source voltage, as well as setting the percentage of peak value if desired. FIG. 11 shows an embodiment of a user interface. This user interface may provide the user the ability to affect the code that one or more processors in the instrument may execute to perform the methods of the embodiments. FIG. 12 shows an embodiment of a test and measurement instrument.

FIG. 12 shows a block diagram of an example test and measurement instrument 60 for implementing the methods of the embodiments. The test and measurement instrument 60 includes one or more input ports 62, which may receive signals from a DUT 68 through a probe or connection 69, and one or more output ports 64 which may be any electrical signaling medium. Ports 62, 64 may include receivers, transmitters, and/or transceivers. Input ports 62 are used to receive signals from an attached device, such as a DUT, a MOSFET, Power MOSFET, WBG device, or other objects being tested. Output ports 64 are used to carry generated signals out of the instrument 60 to be applied to a device or a DUT. Examples of output signals include waveforms as well as constant currents and voltages, and may be applied to the device or devices being tested. Each input port 62 may comprise a channel of the test and measurement instrument 60. The input ports 62 are coupled with one or more processors 66 to process the signals and/or waveforms received at the ports 62 from one or more devices under test. Output ports 64 may be coupled to the processor 66, or other components within the instrument 60 that generate the appropriate output signals. Although FIG. 8 only shows one processor 66 for ease of illustration, as will be understood by one skilled in the art, multiple processors 66 of varying types may be used in combination, rather than a single processor 66.

The input ports 62 can also connect to a measurement unit within the test instrument 60, not depicted here for ease of illustration. Such a measurement unit can include any component capable of measuring aspects, such as voltage, amperage, amplitude, etc., of a signal received via the input ports 62. The output ports 64 can also be connected to various components of the instrument 60, such as voltage sources, current sources, or waveform generators, which are not depicted for ease of illustration. The test and measurement instrument 60 may include additional hardware and/or processors, such as conditioning circuits, an analog to digital converter, and/or other circuitry to convert a received signal to a waveform for further analysis. The resulting waveform can then be stored in a memory 70, as well as displayed on a display 72.

The one or more processors 66 may be configured to execute instructions from memory 70 and may perform any methods and/or associated steps indicated by such instructions, such as displaying values measured to a coupled device according to embodiments of the disclosure. Memory 70 may be implemented as processor cache, random access memory (RAM), read only memory (ROM), solid state memory, hard disk drive(s), or any other memory type. Memory 70 acts as a medium for storing data, computer program products, and other instructions.

User inputs received from the user interface are coupled to the processor 66. User interface 72 may include a keyboard, mouse, trackball, touchscreen, and/or any other controls employable by a user to with a User Interface on the display 72, which may also comprise the user interface. While the components of test instrument 60 are depicted as being integrated within test and measurement instrument 60, it will be appreciated by a person of ordinary skill in the art that any of these components can be external to test instrument 60 and can be coupled to test instrument 60 in any conventional manner.

In this manner, a test and measurement instrument can correctly and accurately determine the output charge Qoss of a device under test, such as a MOSFET, WBG MOSFET, etc.

Aspects of the disclosure may operate on a particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### EXAMPLES

Illustrative examples of the disclosed technologies are provided below. An embodiment of the technologies may include one or more, and any combination of, the examples described below.

Example 1 a test and measurement instrument, comprising: a user interface; one or more probes configured to connect to a device under test (DUT); and one or more processors configured to execute code that causes the one or more processors to: take measurements from the DUT during application of a double pulse test to the DUT to create measurement data; identify a measurement start point in the measurement data; find a measurement stop point in the measurement data; use the measurement data between the measurement start point and the measurement stop point to determine an output charge, Qoss, of the DUT; and display the output charge to a user on the user interface.

Example 2 is the test and measurement instrument of Example 1, wherein the code that causes the one or more processors to take measurements from the DUT further comprises code to cause the one or more processors to take at least one of drain current measurements and low-side drain-source voltage measurements.

Example 3 is the test and measurement instrument of Example 2, wherein the code that causes the one or more processors to identify the measurement start point in the measurement data comprises code that causes the one or more processors to identify a first trough in the drain current and set the measurement start point to be a time of a first zero crossing in the drain current.

Example 4 the test and measurement instrument of Example 3, wherein the code that causes the one or more processors to find the measurement stop point in the measurement data comprises code that causes the one or more processors to find a second zero crossing in the drain current and set a time of the second zero crossing to be the measurement stop point.

Example 5 is the test and measurement instrument of Example 3, wherein the code that causes the one or more processors to find the measurement stop point in the measurement data comprises code that causes the one or more processors to find a point at which the low-side drain-source voltage reaches a threshold, and set a time at which the low-side drain-source voltage reaches the threshold to be the measurement stop point.

Example 6 is the test and measurement instrument of Example 5, wherein the code that causes the one or more processors to find the point at which the low-side drain-source voltage reaches a threshold comprises code that causes the one or more processors to find an occurrence of settling of the drain-source voltage.

Example 7 is the test and measurement instrument of Example 6, wherein the code that causes the one or more processors to find the occurrence of settling of the drain-source voltage comprises code to causes the one or more processors to either receive an input from the user interface that identifies which occurrence of settling is to be used, or uses a first occurrence of settling.

Example 8 is the test and measurement instrument of Example 6, wherein the code that causes the one or more processors to find the point at which the low-side drain-source voltage reaches a threshold comprises code that causes the one or more processors to find a point at which the low-side drain-source voltage has reached a predetermined percentage of a peak drain-source voltage.

Example 9 is the test and measurement instrument of Example 8, wherein the one or more processors are further configured to execute code that causes the one or more processors to receive inputs through the user interface that select the measurement stopping point, and, if the predetermined percentage is used, to set the predetermined percentage.

Example 10 is the test and measurement instrument of any of Examples 1 through 9, wherein the code to that causes the one or more processors to use the measurement data between the first measurement start point and the second measurement stop point comprises code that causes the one or more processors to integrating integrate the drain current over time to find the Qoss.

Example 11 is the test and measurement instrument of any of Examples 1 through 10, wherein the one or more processors are further configured to execute code that causes the one or more processors to allow users to annotate regions of interest on a display.

Example 12 is the method of determining output charge of a device under test (DUT), comprising: taking measurements from the DUT during application of a double pulse test to the DUT to create measurement data; identifying a measurement start point in the measurement data; finding a measurement stop point in the measurement data; using the measurement data between the measurement start point and the measurement stop point to determine the output charge, Qoss, of the DUT; and displaying an output charge to a user on a user interface.

Example 13 is the method of Example 12, wherein taking measurements comprises taking at least one of drain current measurements and low-side drain-source voltage measurements.

Example 14 is the method of Example 13, wherein identifying the measurement start point in the measurement data comprises identifying a first trough in the drain current and setting the measurement start point to be a time of a first zero crossing in the drain current.

Example 15 is the method of Example 14, wherein finding the measurement stop point in the measurement data comprises finding a second zero crossing in the drain current and setting a time of the second zero crossing to be the measurement stop point.

Example 16 is the method of Example 13, wherein finding the measurement stop point in the measurement data comprises finding a point at which the low-side drain-source voltage reaches a threshold, and setting a time at which the low-side drain-source voltage reaches the threshold to be the measurement stop point.

Example 17 is the method of Example 16, wherein finding the point at which the low-side drain-source voltage reaches a threshold comprises either finding an occurrence of settling of the drain-source voltage or using a user-designated occurrence of settling of the drain-source voltage.

Example 18 is the method of Example 16, wherein finding the point at which the low-side drain-source voltage reaches a threshold comprises finding a point at which the low-side drain-source voltage has reached a predetermined percentage of a peak drain-source voltage.

Example 19 is the method of Example 18, further comprising receiving inputs through a user interface to at least configure selection of the measurement stop point, allow the user to annotate regions of interest on the display, and, if the predetermined percentage is used, to set the predetermined percentage.

Example 20 is the method of any of Examples 11 through 19, wherein using the measurement data between the measurement start point and the measurement stop point comprises integrating the drain current over time between the measurement start point and the measurement stop point to find the Qoss.

The previously described versions of the disclosed subject matter have many advantages that were either described or would be apparent to a person of ordinary skill. Even so, these advantages or features are not required in all versions of the disclosed apparatus, systems, or methods.

Additionally, this written description makes reference to particular features. It is to be understood that the disclosure in this specification includes all possible combinations of those particular features. Where a particular feature is disclosed in the context of a particular aspect or example, that feature can also be used, to the extent possible, in the context of other aspects and examples.

Also, when reference is made in this application to a method having two or more defined steps or operations, the defined steps or operations can be carried out in any order or simultaneously, unless the context excludes those possibilities.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

Although specific examples of the invention have been illustrated and described for purposes of illustration, it will be understood that various modifications may be made without departing from the spirit and scope of the invention. Accordingly, the invention should not be limited except as by the appended claims.

1. A test and measurement instrument, comprising:
a user interface;
one or more probes configured to connect to a device under test (DUT); and
one or more processors configured to execute code that causes the one or more processors to:
take measurements from the DUT during application of a double pulse test to the DUT to create measurement data;
identify a measurement start point in the measurement data;
find a measurement stop point in the measurement data;
use the measurement data between the measurement start point and the measurement stop point to determine an output charge, Qoss, of the DUT; and
display the output charge to a user on the user interface.

2. The test and measurement instrument as claimed in claim 1, wherein the code that causes the one or more processors to take measurements from the DUT further comprises code to cause the one or more processors to take at least one of drain current measurements and low-side drain-source voltage measurements.

3. The test and measurement instrument as claimed in claim 2, wherein the code that causes the one or more processors to identify the measurement start point in the measurement data comprises code that causes the one or more processors to identify a first trough in the drain current and set the measurement start point to be a time of a first zero crossing in the drain current.

4. The test and measurement instrument as claimed in claim 3, wherein the code that causes the one or more processors to find the measurement stop point in the measurement data comprises code that causes the one or more processors to find a second zero crossing in the drain current and set a time of the second zero crossing to be the measurement stop point.

5. The test and measurement instrument as claimed in claim 3, wherein the code that causes the one or more processors to find the measurement stop point in the measurement data comprises code that causes the one or more processors to find a point at which the low-side drain-source voltage reaches a threshold, and set a time at which the low-side drain-source voltage reaches the threshold to be the measurement stop point.

6. The test and measurement instrument as claimed in claim 5, wherein the code that causes the one or more processors to find the point at which the low-side drain-source voltage reaches a threshold comprises code that causes the one or more processors to find an occurrence of settling of the drain-source voltage.

7. The test and measurement instrument as claimed in claim 6, wherein the code that causes the one or more processors to find the occurrence of settling of the drain-source voltage comprises code to cause the one or more processors to either receive an input from the user interface that identifies which occurrence of settling is to be used, or use a first occurrence of settling.

8. The test and measurement instrument as claimed in claim 5, wherein the code that causes the one or more processors to find the point at which the low-side drain-source voltage reaches a threshold comprises code that causes the one or more processors to find a point at which the low-side drain-source voltage has reached a predetermined percentage of a peak drain-source voltage.

9. The test and measurement instrument as claimed in claim 8, wherein the one or more processors are further configured to execute code that causes the one or more processors to receive inputs through the user interface that select the measurement stopping point, and, if the predetermined percentage is used, to set the predetermined percentage.

10. The test and measurement instrument as claimed in claim 1, wherein the code that causes the one or more processors to use the measurement data between the measurement start point and the measurement stop point comprises code that causes the one or more processors to integrate the drain current over time to find the Qoss.

11. The test and measurement instrument as claimed in claim 1, wherein the one or more processors are further configured to execute code that causes the one or more processors to allow users to annotate regions of interest on a display.

12. A method of determining output charge of a device under test (DUT), comprising:
taking measurements from the DUT during application of a double pulse test to the DUT to create measurement data;
identifying a measurement start point in the measurement data;
finding a measurement stop point in the measurement data;
using the measurement data between the measurement start point and the measurement stop point to determine an output charge, Qoss, of the DUT; and
displaying the output charge to a user on a user interface.

13. The method as claimed in claim 12, wherein taking measurements comprises taking at least one of drain current measurements and low-side drain-source voltage measurements.

14. The method as claimed in claim 13, wherein identifying the measurement start point in the measurement data comprises identifying a first trough in the drain current and setting the measurement start point to be a time of a first zero crossing in the drain current.

15. The method as claimed in claim 14, wherein finding the measurement stop point in the measurement data comprises finding a second zero crossing in the drain current and setting a time of the second zero crossing to be the measurement stop point.

16. The method as claimed in claim 13, wherein finding the measurement stop point in the measurement data comprises finding a point at which the low-side drain-source voltage reaches a threshold, and a time at which the low-side drain-source voltage reaches the threshold to be the measurement stop point.

17. The method as claimed in claim 16, wherein finding the point at which the low-side drain-source voltage reaches a threshold comprises either finding an occurrence of settling of the drain-source voltage, or using a user-designated occurrence of settling of the drain-source voltage.

18. The method as claimed in claim 16, wherein finding the point at which the low-side drain-source voltage reaches a threshold comprises finding a point at which the low-side drain-source voltage has reached a predetermined percentage of a peak drain-source voltage.

19. The method as claimed in claim 18, further comprising receiving inputs through a user interface to at least configure selection of the measurement stop point, allow the user to annotate regions of interest on the display, and, if the predetermined percentage is used, to set the predetermined percentage.

20. The method as claimed in claim 11, wherein using the measurement data between the measurement start point and the measurement stop point comprises integrating the drain current over time between the measurement start point and the measurement stop point to find the Qoss.
